(19) United States
(12) Patent Application Publication
(10) Pub. No.: US 2012/0109561 A1
(43) Pub. Date: May 3, 2012

(54) WAFER TEST APPARATUS, WAFER TEST METHOD, AND PROGRAM

(75) Inventor: Satoru Terui, Tokyo (JP)

(73) Assignee: Elpida Memory, Inc., Tokyo (JP)

(21) Appl. No.: 13/284,313

(22) Filed: Oct. 28, 2011

(30) Foreign Application Priority Data
Nov. 1, 2010 (JP) 2010-245228

(51) Int. Cl. G06F 19/00; G01R 31/26

(52) U.S. Cl. 702/82

(57) ABSTRACT

A wafer test apparatus, comprises: a storage unit that stores a first test program including a plurality of first operation test programs and a second test program including a plurality of second operation test programs; and a calculation unit that executes the first test program on at least one of wafers in a lot and outputs accumulated information about a defective memory cell(s) included in the wafer to the outside thereof when each operation test of the plurality of first operation tests is completed, and executes the second test program on remaining wafers in the lot and outputs accumulated information about a defective memory cell(s) included in the wafer to the outside thereof when all the operation tests in the plurality of second operation tests are completed.

### REFERENCE TO RELATED APPLICATION

This application is based upon and claims the benefit of the priority of Japanese patent application No. 2010-245228, filed on Nov. 1, 2010, the disclosure of which is incorporated herein in its entirety by reference thereto. The present invention relates to a wafer test apparatus, a wafer test method, and a program. In particular, it relates to a wafer test apparatus, a wafer test method, and a program for testing wafers on which semiconductor devices such as dynamic semiconductor memory devices are formed.

### TECHNICAL FIELD

### Background

When manufactured, semiconductor devices are formed on wafers, and a plurality of wafers are treated as a single group (referred to as a “lot”) (see FIG. 2). Among the recent semiconductor device manufacturing processes, single wafer processing in which wafers are processed one by one is the mainstream, rather than batch processing in which a plurality of wafers are processed collectively.

Whether batch processing or single wafer processing, the process dependence is similar among a plurality of wafers in a single lot. This is because such wafers in a single lot are also processed sequentially in single wafer processing.

A lot is treated as a unit not only when semiconductor devices are formed on a wafer but also in an operation test executed after the semiconductor devices are formed on the wafer.

FIG. 9 is a flow chart illustrating a semiconductor device manufacturing process. In FIG. 9, the semiconductor device manufacturing process includes a pre-process (semiconductor memory chip manufacturing process) (step A1) and a wafer test process (step A2). In addition, the semiconductor device manufacturing process includes a dicing and assembly process (step A3) and a package shipping process (step A4) or a wafer shipping process (step A5).

FIG. 10 is a flow chart illustrating a wafer test process (step A2 in FIG. 9) executed on dynamic random access memories (DRAMs) as semiconductor devices. In FIG. 10, the wafer test process includes: a burn-in (stress application) process (step B1), a pre-redundancy-repair-test process (step B2), a fuse trimming process (step B3), and a post-redundancy-repair-test process (step B4).

In the burn-in process (step B1), to apply stress, DRAMs are subjected to high temperatures, high voltages, and the like. In the pre-redundancy-repair-test process (step B2), a plurality of data patterns are written in the DRAMs to which stress has been applied, and the data patterns are read from the DRAMs, so as to detect defective cells. In the fuse trimming process (step B3), the detected defective cells are replaced with redundant memory cells. In the post-redundancy-repair-test process (step B4), again, a plurality of data patterns are written in the DRAMs in which the defective memory cells have been replaced, and the data patterns are read from the DRAMs, so as to check whether or not the DRAMs have been repaired properly.

### Patent Document 1:

Japanese Patent Kokai Publication No. JP2002-134569A

### Patent Document 2:

Japanese Patent Kokai Publication No. JP2004-296826A

### SUMMARY

The entire disclosures of above mentioned Patent Documents are incorporated herein by reference thereto. The following analyses are made by the present inventor.

In the pre-redundancy-repair-test process (step B2 in FIG. 10) of the above DRAM wafer test, a plurality of data patterns corresponding to a plurality of possible defective patterns are written and read sequentially. Each of these writing and reading operations is referred to as an “operation test.”

Based on conventional wafer test apparatuses, results of such sequentially-executed operation tests are accumulated and stored, and users can grasp, for example, arrangement of defective cells after all the operation tests are completed. However, based on these wafer test apparatuses, users cannot detect which cell or cells be determined to be defective in each of the operation tests. In other words, users cannot detect defective patterns of detected defective cells.

Each of a plurality of defective patterns of DRAMs is often caused by variations in corresponding process conditions and the like. Thus, to promptly detect variations in process conditions and provide feedback for product development, it is important to grasp the defective patterns of the individual defective cells.

Patent Documents 1 and 2 disclose a wafer test apparatus sequentially storing defective memory information per operation test. However, according to Patent Documents 1 and 2, defective memory cell information per operation test executed on all wafers is sequentially stored. In this way, since the wafer test apparatus requires a large-capacity memory, the cost of the wafer test apparatus is increased, counted as a problem.

Thus, the following method is conceivable as a method for detecting defective patterns of detected defective cells, without increasing the memory capacity of the wafer test apparatus. More specifically, the method includes: accumulating and storing results of sequentially-executed operation tests; outputting defective memory cell information to the outside of the wafer test apparatus for each operation test; and subtracting defective memory cell information obtained from a previous operation test from defective memory cell information obtained from an ongoing operation test being executed to detect defective memory cells.

However, it is time-consuming to output defective memory cell information to the outside of the wafer test apparatus. If test results per operation test for all wafers be outputted to the outside of the wafer test apparatus, the test time is increased, counted as a problem. Thus, there is a need in the art to provide a wafer test apparatus, a wafer test method, and a program for testing, capable of detecting defective patterns of detected defective cells, without increasing the test time.

According to a first aspect of the present invention, there is provided a wafer test apparatus, which comprises:

a storage unit that stores a first test program including a plurality of first operation test programs and a second test program including a plurality of second operation test programs; and
a calculation unit that executes the first test program on at least one of wafers in a lot and outputs accumulated information about a defective memory cell(s) included in the wafer to the outside thereof when each operation test of the plurality of first operation tests is completed, and executes the second test program on remaining wafers in the lot and outputs accumulated information about a defective memory cell(s) included in the wafer to the outside thereof when all the operation tests in the plurality of second operation tests are completed.

According to a second aspect of the present invention, there is provided a wafer test method, which comprises:

executing a first test program including a plurality of first operation test programs on at least one of wafers in a lot and outputting accumulated information about a defective memory cell(s) included in the wafer to the outside of a wafer test apparatus when each operation test of the plurality of first operation tests is completed; and
executing a second test program including a plurality of second operation test programs on remaining wafers in the lot and outputting accumulated information about a defective memory cell(s) included in the wafer to the outside of the wafer test apparatus when all the operation tests in the plurality of second operation tests are completed.

According to a third aspect of the present invention, there is provided a program that causes a computer to execute:

executing a first test program including a plurality of first operation test programs on at least one of wafers in a lot and outputting accumulated information about a defective memory cell(s) included in the wafer to a storage device when each operation test of the plurality of first operation tests is completed; and
executing a second test program including a plurality of second operation test programs on remaining wafers in the lot and outputting accumulated information about a defective memory cell(s) included in the wafer to the storage device when all the operation tests in the plurality of second operation tests are completed.
The program may be recorded on (or embodied in) a non-transient storage device which is computer readable.

The present invention provides the following advantage, but not restricted thereto. Based on the wafer test apparatus, the wafer test method, and the program according to the present invention, defective patterns of detected defective cells can be detected, without increasing the wafer test time.

### BRIEF DESCRIPTION OF THE DRAWINGS

FIG. 1 is a block diagram schematically illustrating a configuration of a wafer test apparatus.

FIG. 2 schematically illustrates a lot, wafers, and chips.

FIG. 3 illustrates a connection configuration of a test system including a wafer test apparatus according to a first exemplary embodiment.

FIG. 4 is a block diagram illustrating a configuration of the wafer test apparatus according to the first exemplary embodiment.

FIG. 5 is a flow chart illustrating details of a pre-redundancy-repair test according to the first exemplary embodiment.

FIG. 6 is a flow chart illustrating an operation of a first test program according to the first exemplary embodiment.

FIG. 7 is a flow chart illustrating an operation of a second test program according to the first exemplary embodiment.

FIG. 8 illustrates a connection configuration of a test system including a wafer test apparatus according to a second exemplary embodiment.

FIG. 9 is a flow chart illustrating a semiconductor device manufacturing process.

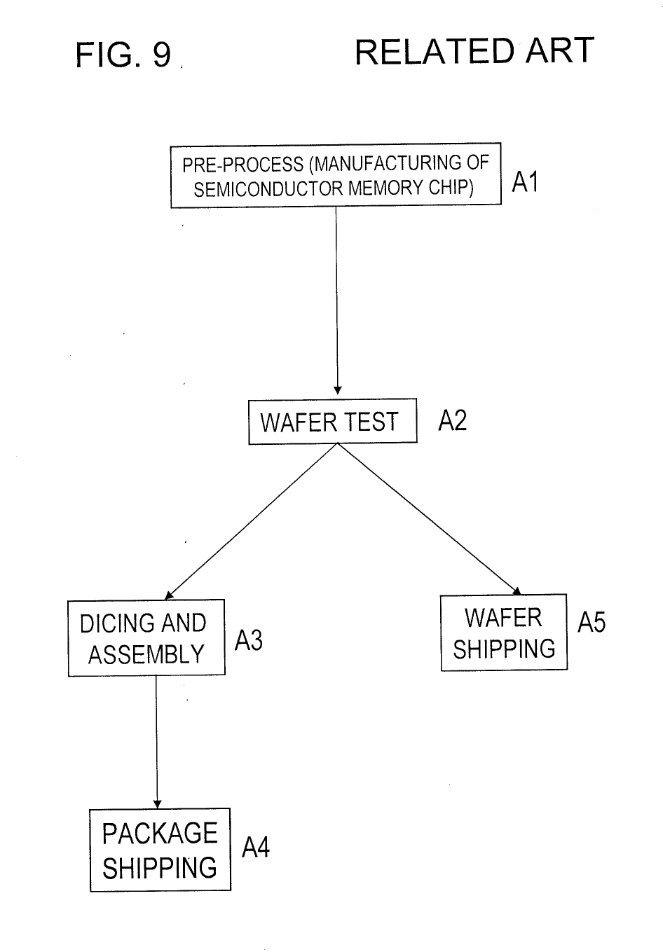

FIG. 10 is a flow chart illustrating details of a wafer test.

### PREFERRED MODES

In the present disclosure, there are various possible modes, which include the following, but not restricted thereto. First, an outline of the present invention will be described. The reference symbols in this outline are used only as examples to facilitate comprehension and are not intended to limit the present invention to the illustrated modes.

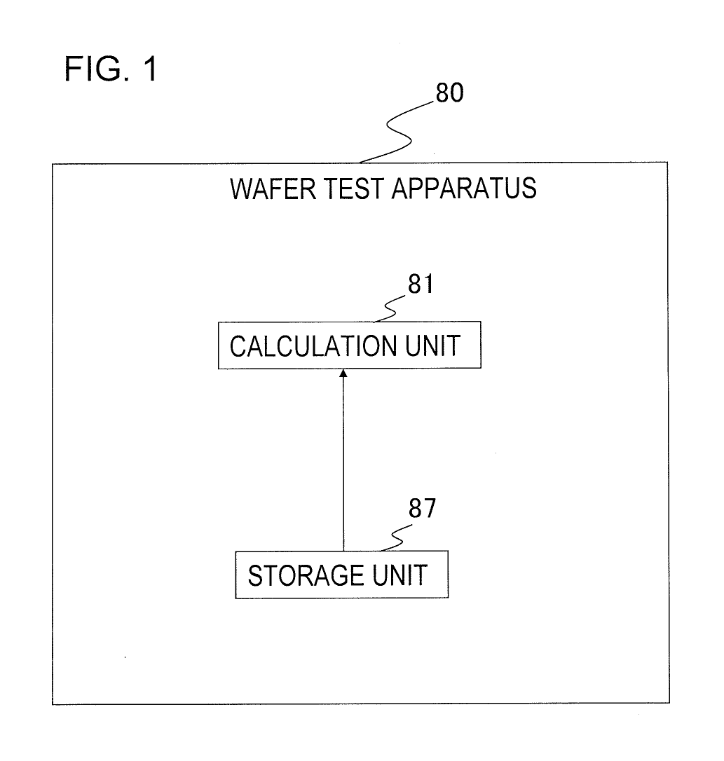

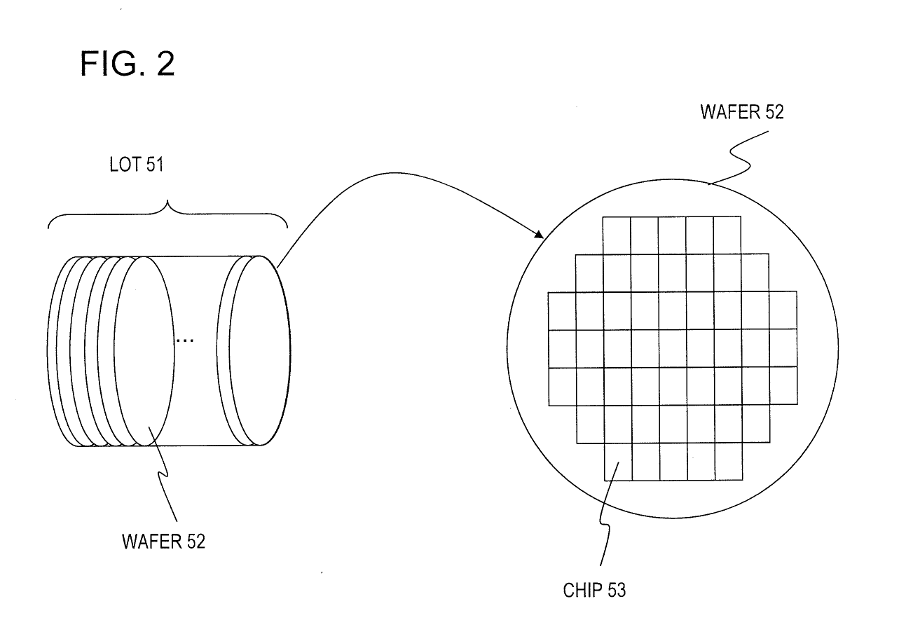

In FIG. 1, it is preferable that a wafer test apparatus (80) comprise: a storage unit (87) that stores a first test program and a second test program; and a calculation unit (81) that tests some of a plurality of wafers in a lot (see FIG. 2) with the first test program and tests the remaining wafers of the plurality of wafers in the lot with the second test program.

It is preferable that the first test program execute a plurality of operation tests on a wafer and output accumulated information about a defective memory cell(s) included in the wafer to the outside of the wafer test apparatus (80) each time an operation test is completed. On the other hand, it is preferable that the second test program execute the plurality of operation tests on a wafer and output accumulated information about a defective memory cell(s) included in the wafer to the outside of the wafer test apparatus (80) after all the operation tests are completed.

In addition, if the calculation unit (81) detects that a predetermined number of wafers among the plurality of wafers have been tested with the first test program, the calculation unit (81) may replace the first test program with the second test program.

In addition, it is preferable that the calculation unit (81) determine whether to replace the first test program with the second test program based on test results of the some of the wafers. For example, if none of the test results of the some of the wafers deviates from a predetermined reference value, the calculation unit (81) may replace the first test program with the second test program.

According to the present invention, by testing some of a plurality of wafers in a single lot having similar process dependence with the first test program, defective patterns of detected defective cells can be detected. In addition, by testing the remaining wafers in the single lot with the second test program, an increase of the test time can be prevented.

Thus, based on the wafer test apparatus according to the present invention, defective patterns of detected defective cells can be detected, without increasing the wafer test time. Further, the program (or recording medium recording the program) may be incorporated in a wafer test apparatus as a part (or component) thereof. Alternatively, the program may be supplied to the wafer test apparatus through communication lines or network from an external source (database).

### Exemplary Embodiment 1

A wafer test apparatus according to a first exemplary embodiment will be described with reference to the drawings.

FIG. 2 schematically illustrates a lot 51, wafers 52, and chips 53. In FIG. 2, a plurality of chips 53 are formed on a wafer 52. The lot 51 is formed by a plurality of wafers 52 as a unit. For example, a group of 25 wafers corresponds to a single lot.

A plurality of wafers in a single lot are processed collectively or sequentially in a manufacturing process in a single manufacturing apparatus. Since variations in quality during manufacture, that is, variations in chip characteristics, depend on process variations in the manufacturing process, variations in quality are small among such plurality of wafers in a single lot processed sequentially or continuously.

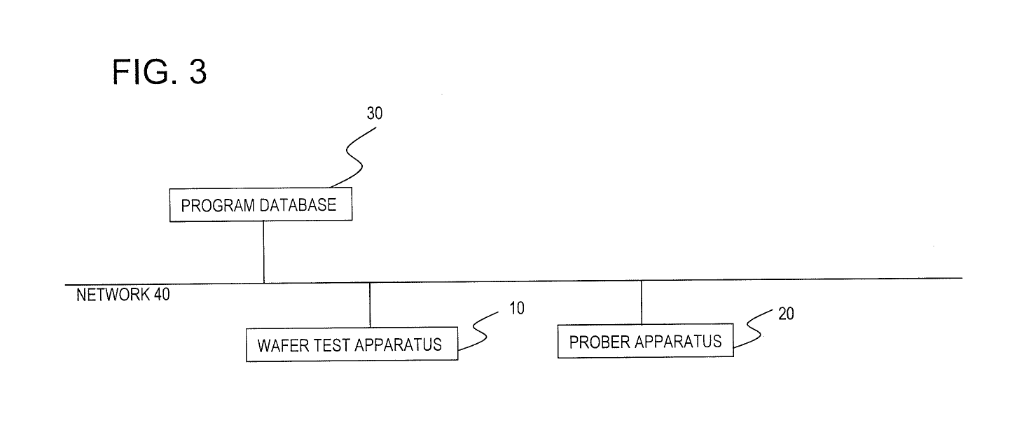

FIG. 3 illustrates a connection configuration of a test system including a wafer test apparatus 10 according to the present exemplary embodiment. In FIG. 3, the test system includes the wafer test apparatus 10, a prober apparatus 20, and a program database 30, all of which are connected to each other via a network 40.

The prober apparatus 20 connects the wafer test apparatus 10 and wafers 52 and inputs/outputs signals. In addition, the prober apparatus 20 tests a group of wafers 52 as a single lot 51. By inputting states (types, steps, and the like) of the lot 51, a test corresponding to the states is executed. The program database 30 stores programs for the individual product types. Programs A and B are switched in a program or a system.

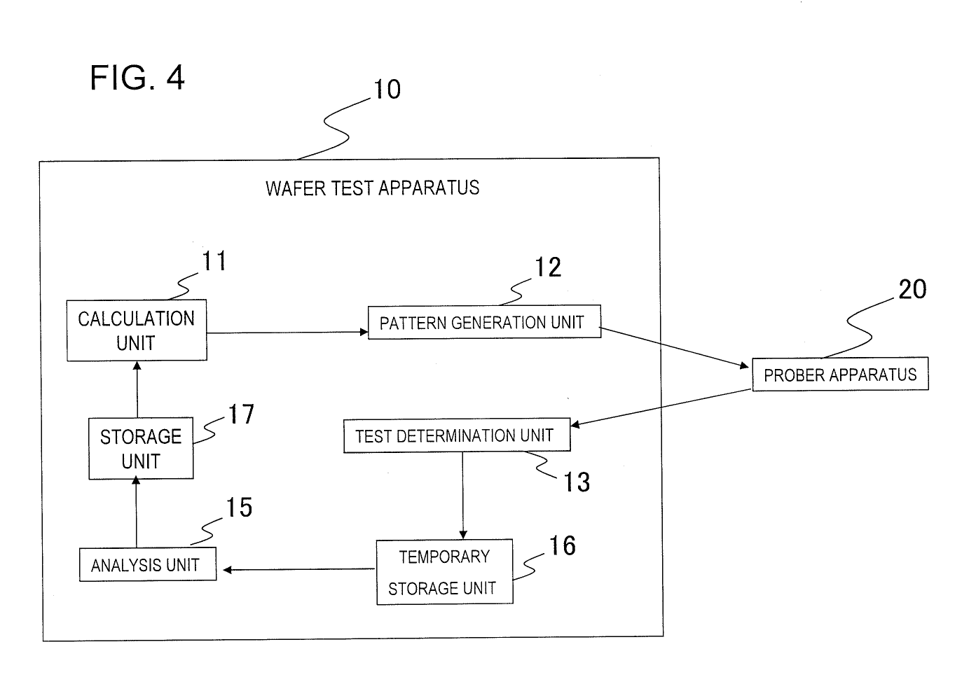

FIG. 4 is a block diagram illustrating a configuration of the wafer test apparatus 10. In FIG. 4, the wafer test apparatus 10 comprises a calculation unit 11, a pattern generation unit 12, a test determination unit 13, an analysis unit 15, a temporary storage unit 16, and a storage unit 17.

The calculation unit 11 (CPU, for example) controls the wafer test apparatus 10 and the programs. The calculation unit 11 determines whether the programs need to be switched based on repair calculation results that are created by the analysis unit 15 and that are stored in the storage unit 17 and controls the programs.

The pattern generation unit 12 receives data pattern information in a program from the calculation unit 11 and creates a test waveform.

The test determination unit 13 determines Pass or Fail of an operation test based on data outputted from chips 53.

The analysis unit 15 receives results from the test determination unit 13 and executes a replacement determination based on defective cell location information.

The storage unit 17 stores files such as programs read from the program database 30 and results from the analysis unit 15.

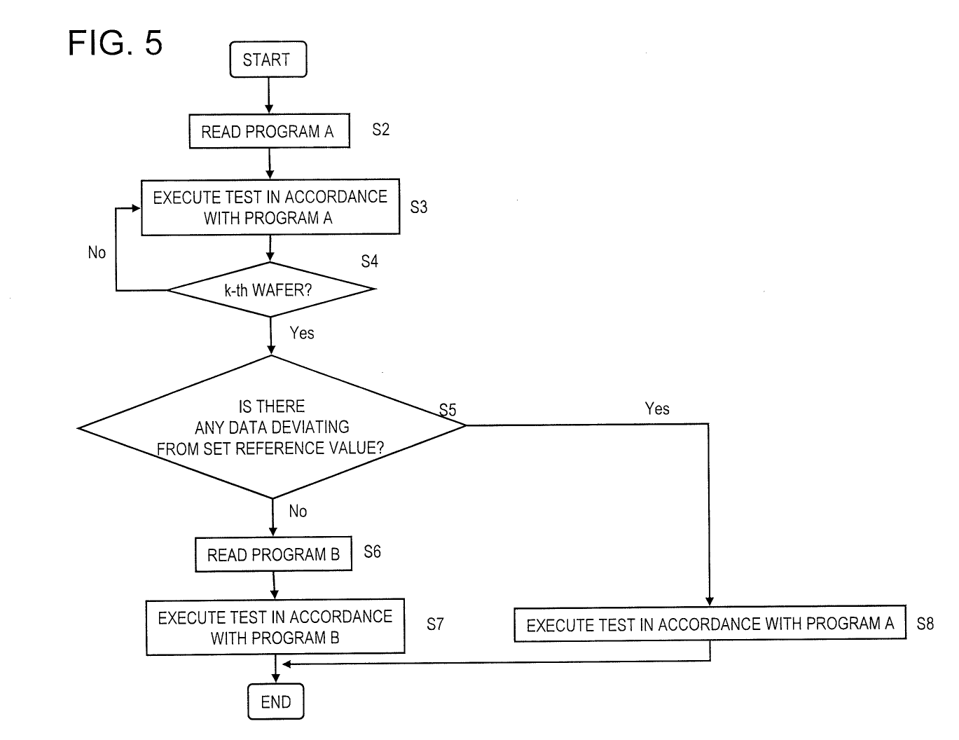

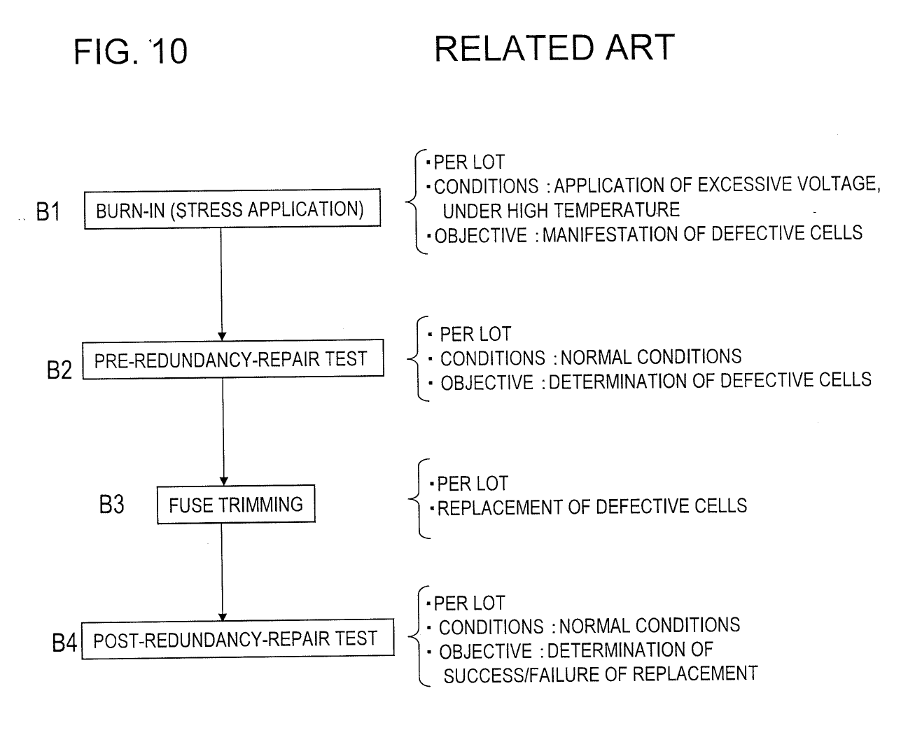

FIG. 5 is a flow chart illustrating details of a pre-redundancy-repair test (corresponding to step B2 in FIG. 10) according to the present exemplary embodiment.

First, the prober apparatus 20 reads lot information, reads the programs A and B corresponding to a lot 51 from the program database 30, and stores the programs A and B in the storage unit 17 of the wafer test apparatus 10.

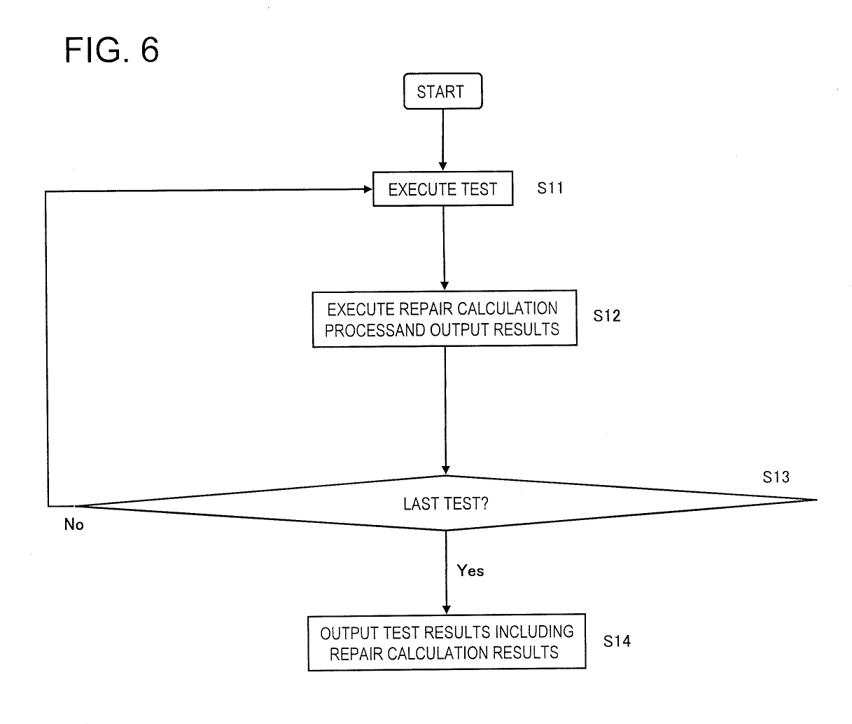

The calculation unit 11 reads the program A stored in the storage unit 17 (step S2). An operation test is executed on a single wafer in accordance with a flow chart of the program A in FIG. 6, and repair calculation results and test results are outputted (step S3).

Next, wafer information sent from the prober apparatus 20 is checked, and whether or not the tested wafer is a k-th wafer (k is an arbitrary positive integer) previously set in the program A is determined (step S4). If the tested wafer is not the k-th wafer (No in step S4), the operation returns to step S3, and the operation test is continued in accordance with the program A until the k-th wafer is determined.

On the other hand, if the tested wafer is determined to be the k-th wafer (Yes in step S4), data about the first to k-th wafers outputted to the storage unit 17 is compared with a reference value X previously set in the program A. Next, whether any data deviates from the reference value X (any data that needs to be considered as poor quality) is determined (step S5).

If none of the data deviates from the reference value X (No in step S5), the calculation unit 11 stops running the program A and reads the program B stored in the storage unit 17 in step S1 (step S6).

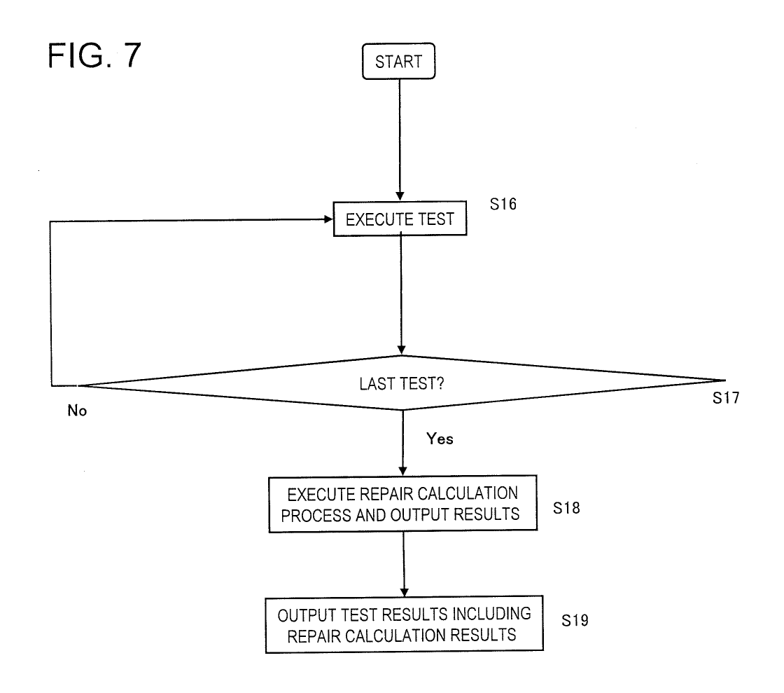

Next, in accordance with a flow chart of the program B in FIG. 7, an operation test is executed (step S7).

If any data deviates from the reference value X (Yes in step S5), the calculation unit 11 does not change the program A but continues to use the program A to acquire the remaining data (step S8).

FIG. 6 is a flow chart illustrating details of the program A. Namely, FIG. 6 illustrates contents of the test (steps S3 and S8 in FIG. 5) executed in accordance with the program A.

In accordance with the program A read by the calculation unit 11, at least one operation test is executed (step S11). In this step, the test determination unit 13 checks test results from data outputted from chips and accumulates defective cell information in the temporary storage unit 16.

The analysis unit 15 uses the information accumulated in the temporary storage unit 16 in step S11 and analysis results outputted to the storage unit 17 in a previous repair calculation process, to execute a repair calculation process. The analysis unit 15 next outputs analysis results to the storage unit 17 (step S12).

Next, whether or not the test is the last test in the flow is determined (step S13). If the test is not the last test in the flow (No in step S13), steps S11 to S13 are repeated until all the tests are executed.

If the last test is completed (Yes in step S13), test results including repair calculation results are outputted to the storage unit 17 (step S14).

FIG. 7 is a flow chart illustrating details of the program B. Namely, FIG. 7 illustrates contents of the test (step S7 in FIG. 5) executed in accordance with the program B.

As in the case of the test executed in accordance with the program A (step S11 in FIG. 6), a plurality of operation tests are executed, and defective cell information is accumulated in the temporary storage unit 16 (step S16).

Next, whether or not the test is the last test in the flow is determined (step S17). If the test is not the last test in the flow (No in step S17), steps S16 and S17 are repeated until all the tests are executed.

If the last test is completed (Yes in step S17), the analysis unit 15 executes a repair calculation process on defective cell information acquired from all the tests and accumulated in the temporary storage unit 16 and outputs the results to the storage unit 17 (step S18).

Next, the analysis unit 15 outputs test results including repair calculation results to the storage unit 17 (step S19).

Based on the wafer test apparatus 10 according to the present exemplary embodiment, by testing some of a plurality of wafers in a single lot having similar process dependence with a first test program (program A), defective patterns of detected defective cells can be detected. In addition, by testing the remaining wafers in the single lot with a second test program (program B), an increase of the test time can be prevented.

### Exemplary Embodiment 2

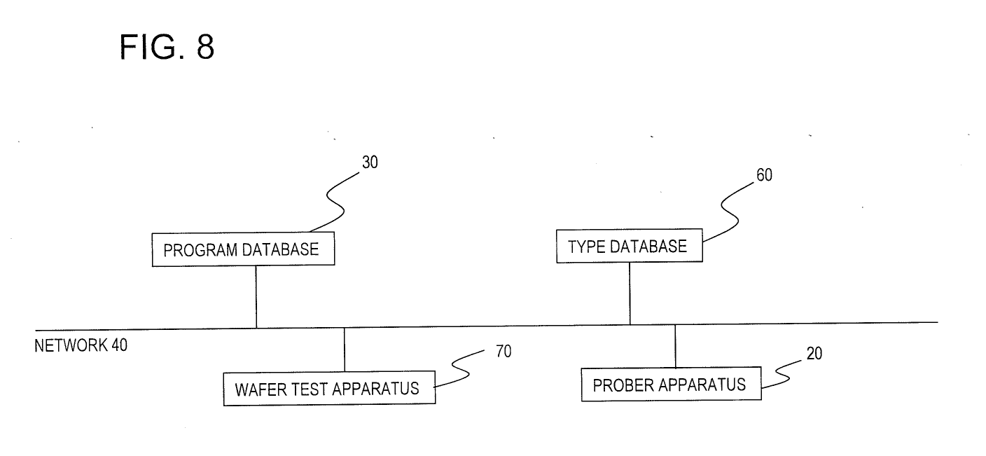

A wafer test apparatus according to a second exemplary embodiment will be described with reference to the drawings. FIG. 8 illustrates a connection configuration of a test system including a wafer test apparatus 70 according to the present exemplary embodiment.

In FIG. 8, the test system includes the wafer test apparatus 70, the prober apparatus 20, the program database 30, and a type database 60, all of which are connected to each other via the network 40.

The type database 60 is a database for parameters that are set for each type of chips mounted on wafers. Examples of the parameters include the wafer number k and the reference value X used for quality determination according to the first exemplary embodiment.

According to the first exemplary embodiment, in steps S4 and S5, the wafer number k and the reference value X used for quality determination are set in the program A. However, according to the present exemplary embodiment, since the wafer test apparatus 70 or the type database 60 are coordinated, the wafer number k and the reference value X can be set in the type database 60, instead of in the program A.

In this way, the need for setting the wafer number k and the reference value X in the program A is eliminated. Thus, according to the present exemplary embodiment, quality standards can be managed and changed easily, without preparing a new program. Thus, man-hours for creating programs can be reduced, and rapid mass production can be realized.

The entire disclosures of the above Patent Documents are incorporated herein in its entirety by reference thereto. Modifications and adjustments of the exemplary embodiments and examples are possible within the scope of the overall disclosure (including the claims) of the present invention and based on the basic technical concept of the present invention. Various combinations and selections of various disclosed elements are possible within the scope of the claims of the present invention. That is, the present invention of course includes various variations and modifications that could be made by those skilled in the art according to the overall disclosure including the claims and the technical concept.

What is claimed is:

1. A wafer test apparatus, comprising:
a storage unit that stores a first test program including a plurality of first operation test programs and a second test program including a plurality of second operation test programs; and
a calculation unit that executes the first test program on at least one of wafers in a lot and outputs accumulated information about a defective memory cell(s) included in the wafer to the outside thereof when each operation test of the plurality of first operation tests is completed, and executes the second test program on remaining wafers in the lot and outputs accumulated information about a defective memory cell(s) included in the wafer to the outside thereof when all the operation tests in the plurality of second operation tests are completed.

2. The wafer test apparatus according to claim 1, wherein
the calculation unit replaces the first test program with the second test program when the calculation unit detects that a predetermined number of wafers among the plurality of wafers have been tested with the first test program.

3. The wafer test apparatus according to claim 2, wherein
the calculation unit determines whether to replace the first test program with the second test program based on test results of the execution of the first test program.

4. The wafer test apparatus according to claim 3, wherein
when none of the test results of the execution of the first test program deviates from a predetermined reference value, the calculation unit replaces the first test program with the second test program.

5. The wafer test apparatus according to claim 2, further comprising:
a type database that stores the predetermined number for each type of chips formed on wafers, wherein
the calculation unit refers to the type database to determine whether or not a predetermined number of wafers among the plurality of wafers have been tested.

6. The wafer test apparatus according to claim 4, further comprising:
a type database that stores the predetermined reference value for each type of chips formed on wafers, wherein
the calculation unit refers to the type database to determine whether or not any of the test results of the some of the wafers deviates from a predetermined reference value.

7. A wafer test method, comprising:
executing a first test program including a plurality of first operation test programs on at least one of wafers in a lot and outputting accumulated information about a defective memory cell(s) included in the wafer to the outside of a wafer test apparatus when each operation test of the plurality of first operation tests is completed; and
executing a second test program including a plurality of second operation test programs on remaining wafers in the lot and outputting accumulated information about a defective memory cell(s) included in the wafer to the outside of the wafer test apparatus when all the operation tests in the plurality of second operation tests are completed.

8. The wafer test method according to claim 7, further comprising:
replacing the first test program with the second test program when a predetermined number of wafers among the plurality of wafers have been tested with the first test program.

9. The wafer test method according to claim 8, further comprising:
determining whether to replace the first test program with the second test program based on test results of the execution of the first test program.

10. The wafer test method according to claim 9, wherein
in the determination, when none of the test results of the execution of the first test program deviates from a predetermined reference value, the first test program is replaced with the second test program.

11. A program, causing a computer to execute:
executing a first test program including a plurality of first operation test programs on at least one of wafers in a lot and outputting accumulated information about a defective memory cell(s) included in the wafer to a storage device when each operation test of the plurality of first operation tests is completed; and
executing a second test program including a plurality of second operation test programs on remaining wafers in the lot and outputting accumulated information about a defective memory cell(s) included in the wafer to the storage device when all the operation tests in the plurality of second operation tests are completed.
